(19) United States
(12) Patent Application Publication
(10) Pub. No.: US 2017/0263893 A1
(43) Pub. Date: Sep. 14, 2017

(54) METHOD FOR MANUFACTURING LIGHT EXTRACTION SUBSTRATE FOR ORGANIC LIGHT-EMITTING DIODE, LIGHT EXTRACTION SUBSTRATE FOR ORGANIC LIGHT-EMITTING DIODE, AND ORGANIC LIGHT-EMITTING DIODE INCLUDING SAME

(71) Applicant: Corning Precision Materials Co., Ltd., Chungcheongnam-do (KR)

(72) Inventors: Dong Hyun Kim, Chungcheongnam-do (KR); Seo Hyun Kim, Chungcheongnam-do (KR); Eui Soo Kim, Chungcheongnam-do (KR); Kyoung Wook Park, Chungcheongnam-do (KR); Il Hee Baek, Chungcheongnam-do (KR); Chang Min Song, Chungcheongnam-do (KR); Gun Sang Yoon, Chungcheongnam-do (KR); Hong Yoon, Chungcheongnam-do (KR); Joo Young Lee, Chungcheongnam-do (KR); Hyun Hee Lee, Chungcheongnam-do (KR); Eun Ho Choi, Chungcheongnam-do (KR)

(73) Assignee: Corning Precision Materials Co., Ltd., Chungcheongnam-do (KR)

(21) Appl. No.: 15/508,732

(22) PCT Filed: Sep. 3, 2015
(86) PCT No.: PCT/KR2015/009272

§ 371 Date: Mar. 3, 2017

(30) Foreign Application Priority Data
Sep. 5, 2014 (KR) 10-2014-0118893

(51) Int. Cl. H01L 51/52; C23C 14/48; H01L 51/56

(52) U.S. Cl. CPC H01L 51/5268; H01L 51/56; H01L 51/5215; C23C 14/48; H01L 2251/303

(57) ABSTRACT

The present invention relates to a method for manufacturing a light extraction substrate for an organic light-emitting diode and, more specifically, to a method for manufacturing a light extraction substrate for an organic light-emitting diode, which can improve light extraction efficiency of an organic light-emitting diode and can also remarkably reduce a manufacturing process, manufacturing costs, and manufacturing time. To this end, the present invention provides a method for manufacturing a light extraction substrate for an organic light-emitting diode, the method comprising: an ion injection step of injecting, into the inside of the base material, an ion from one side of a base material arranged on a transparent electrode of an organic light-emitting diode, so as to form an ion injection layer inside the base material; and a heat treatment step of forming, inside the base material, a pore layer having a plurality of pores having a different refractive index from that of the base material, through the application of thermal energy to the ion injection layer, wherein the plurality of pores are induced through the gasification of the ion.

### TECHNICAL FIELD

The present disclosure relates to a method of manufacturing a light extraction substrate for an organic light-emitting diode (OLED) device. More particularly, the present disclosure relates to a method of manufacturing a light extraction substrate for an OLED device that can improve the light extraction efficiency of the OLED device, significantly simplify the manufacturing process of the OLED device, and significantly reduce the manufacturing costs and manufacturing time of the OLED device.

### BACKGROUND ART

Generally, an organic light-emitting diode (OLED) is comprised of an anode, a light-emitting layer, and a cathode. Here, when a voltage is induced between the anode and the cathode, holes from the anode are injected into a hole injection layer, from which holes migrate to an emission layer through a hole transport layer, while electrons from the cathode are injected into an electron injection layer, from which electrons migrate to the emission layer through an electron transport layer. The electrons and the holes that have migrated into the emission layer recombine with each other, thereby generating excitons. When these excitons transit from an excited state to a grounded state, light is emitted.

Organic light-emitting diode display devices including such OLEDs are divided into passive matrix organic light-emitting diode display devices and active matrix organic light-emitting diode display devices according to the driving modes of N×M number of pixels arranged in a matrix pattern utilized thereby.

In the case of active matrix organic light-emitting diode display devices, a pixel electrode defining an emission region and a unit pixel driving circuit for applying an electric current or a voltage to the pixel electrode are disposed in a unit pixel area. The unit pixel driving circuit includes at least two thin-film transistors (TFTs) and a single capacitor to enable the supply of a certain amount of electric current, irrespective of the number of pixels, thereby obtaining a reliable level of luminance. Such active matrix organic light-emitting diode display devices may be adaptable to high resolution and large displays, due to having reduced power consumption.

However, in the case of a planar OLED-based lighting device, at least half of light generated by the light-emitting layer is lost by reflection or absorption inside of or at the boundaries of the diode due to the thin film multilayer structure, instead of exiting forwards. Thus, an additional amount of current must be applied to obtain a desired level of luminance. In this case, however, power consumption may increase, thereby reducing the lifetime of the diode.

To overcome this problem, a technology for forwardly extracting light that would otherwise be lost in the interior or boundaries of an OLED is required. This technology is referred to as light extraction technology. A problem solving scheme based on the light extraction technology is intended to remove any factor that prevents light from traveling forwards, so that that the light is lost inside of or at the boundaries of the OLED, or to disturb the travel of light. In this regard, external light extraction methods and internal light extraction methods are typically used. External light extraction methods are devised to reduce total internal reflection at the boundary between a substrate and the surrounding air by forming textures in the surface of the outermost portion of the substrate or coating the outermost portion with a layer having a different refractive index from the substrate. Internal light extraction methods are devised to reduce a waveguide effect in which light travels along the boundary between layers having different refractive indices and thicknesses instead of traveling forwards through the boundary, by forming surface textures between a substrate and a transparent electrode or forming a coating layer having a different refractive index from the substrate between a substrate and a transparent electrode.

However, conventional light extraction technology or light extraction layer forming methods as described above require the use of complicated processing methods, such as a photolithography, and expensive equipment, which are problematic. Even in the case in which surface textures are formed between the substrate and the transparent electrode, a planarization layer must be additionally formed between the surface textures and the transparent electrode. This consequently results in complicated manufacturing processing, increased manufacturing costs, and increased manufacturing time, which are problematic.

### RELATED ART DOCUMENT

United States Patent Application Publication No. 2012-0049151 (Mar. 1, 2012)

### DISCLOSURE

### Technical Problem

Accordingly, the present disclosure has been made in consideration of the above problems occurring in the related art, and the present disclosure proposes a method of manufacturing a light extraction substrate for an organic light-emitting diode (OLED) device that can improve the light extraction efficiency of the OLED device, significantly simplify the manufacturing process of the OLED device, and significantly reduce the manufacturing costs and manufacturing time of the OLED device.

### Technical Solution

According to the present disclosure, a method of manufacturing a light extraction substrate for an organic light-emitting diode (OLED) device may include: forming an ion implantation layer within a base to be disposed on a transparent electrode of an OLED by implanting ions into the base through a surface of the base; and forming a void layer including a number of voids within the base by applying heat energy to the ion implantation layer, a refractive index of the number of voids being different from a refractive index of the base, wherein the number of voids are induced by gasification of the ions.

The base may be a transparent substrate formed from a thermally or ultraviolet curable polymeric material, soda-lime glass, or aluminosilicate glass.

In addition, the ions used in the step of forming the ion implantation layer may be formed from at least one selected from a candidate group consisting of H₂, Ar, He, and N₂.

According to the present disclosure, a method of manufacturing a light extraction substrate for an (OLED) device may include: forming a metal oxide layer on a base, the metal oxide layer being formed from a metal oxide having a first refractive index; forming an ion implantation layer within the metal oxide layer by implanting ions into the metal oxide layer through a surface of the metal oxide layer; and forming a void layer including a number of voids within the metal oxide layer by applying heat energy to the ion implantation layer, the number of voids having a second refractive index, wherein the number of voids are induced by gasification of the ions.

The metal oxide used in the step of forming the metal oxide layer may be one selected from the group consisting of ZnO, Al₂O₃, TiO₂, SnO₂, ZrO₂, and SiO₂.

The ions used in the step of forming the ion implantation layer may be formed from at least one selected from a candidate group consisting of H₂, Ar, He, and N₂.

An exposed surface of the metal oxide layer may be to be in contact with a transparent electrode of an organic light-emitting diode.

### Advantageous Effects

As set forth above, according to the present disclosure, it is possible to induce the formation of voids within a substrate acting as a light extraction layer of an OLED device by implanting ions into the substrate and then applying heat energy to the implanted ions. Since a single substrate can be imparted with two refractive indices, the light extraction efficiency of an OLED device can be improved.

In addition, according to the present disclosure, it is possible to significantly simplify a manufacturing process and significantly reduce manufacturing costs and manufacturing time by forming a number of voids within a substrate by a simple process including ion implantation and heat treatment.

### DESCRIPTION OF DRAWINGS

FIG. 1 to FIG. 3 are process views illustrating a method of manufacturing a light extraction substrate for an OLED device according to one embodiment of the present disclosure, in the sequence of processes;

FIG. 4 is a cross-sectional view schematically illustrating an OLED device, with the light extraction substrate manufactured according to the one embodiment of the present disclosure being disposed in a top portion thereof;

FIG. 5 to FIG. 8 are process views illustrating a method of manufacturing a light extraction substrate for an OLED device according to another embodiment of the present disclosure, in the sequence of processes; and

FIG. 9 is a cross-sectional view schematically illustrating an OLED device, with the light extraction substrate manufactured according to the another embodiment of the present disclosure being disposed in a top portion thereof.

### MODE FOR INVENTION

Hereinafter, a method of manufacturing a light extraction substrate for an organic light-emitting diode (OLED) device according to embodiments of the present disclosure will be described in detail with reference to the accompanying drawings.

In the following description, detailed descriptions of known functions and components incorporated herein will be omitted in the case that the subject matter of the present disclosure may be rendered unclear by the inclusion thereof.

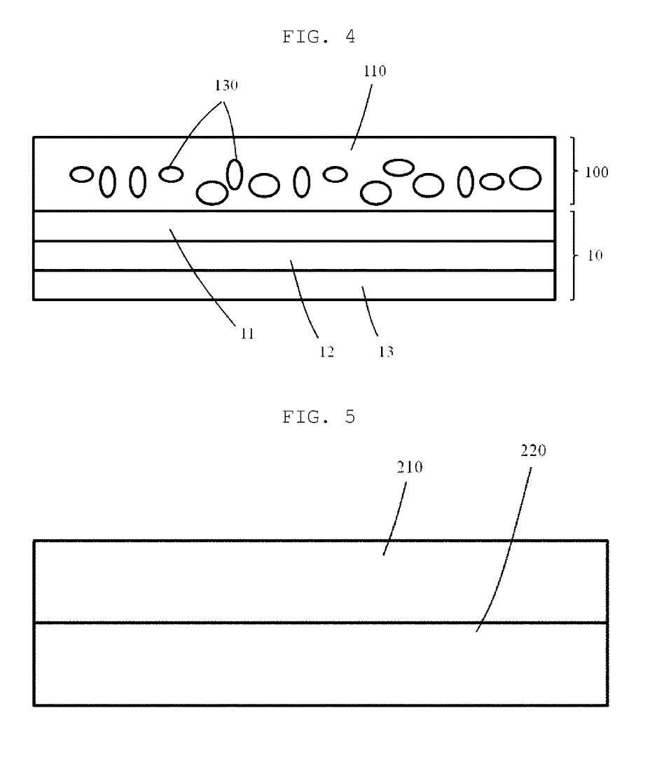

As illustrated in FIG. 4, a method of manufacturing a light extraction substrate for an OLED device according to one embodiment of the present disclosure is a method of manufacturing a light extraction substrate 100 provided in a portion of an OLED device, through which light generated by an OLED 10 of the OLED device exits, to act as a pathway, along which light generated by the OLED 10 exits, so that the light extraction efficiency of the OLED device is improved, and to protect the OLED 10 from the external environment.

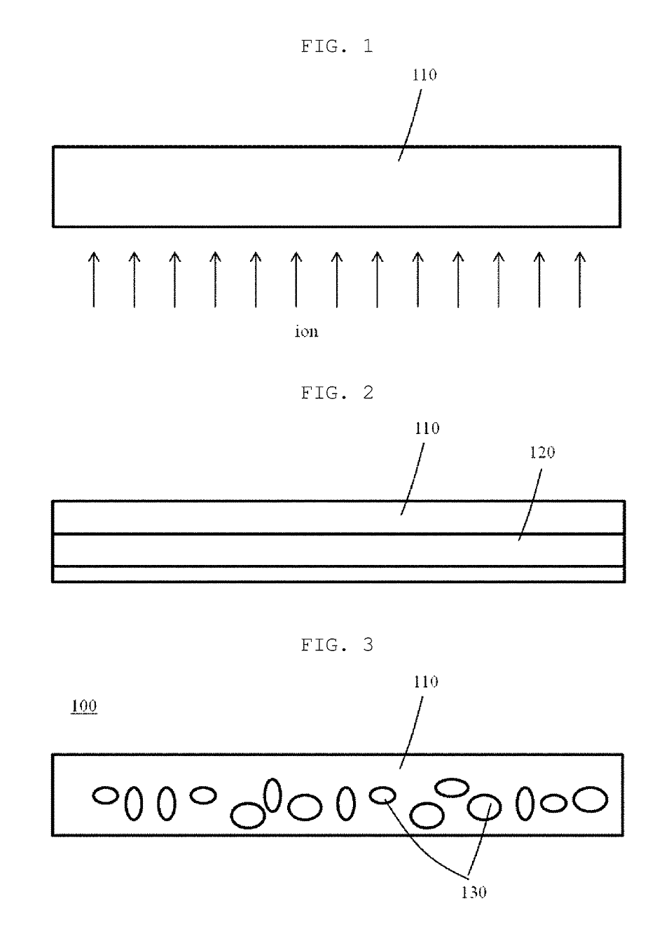

The method of manufacturing a light extraction substrate for an OLED device according to the one embodiment of the present disclosure includes an ion implantation step and a heat treatment step. mom As illustrated in FIG. 1 and FIG. 2, the ion implantation step is a step of forming an ion implantation layer 120 within a base 110. The base 110 acts as not only a light extraction layer of the OLED device (FIG. 4) but also as an encapsulation substrate protecting the OLED 10 (FIG. 4) from the external environment. The base 110 may be formed from any material having superior light transmittance and mechanical properties. For example, the base 110 may be formed from a polymeric material, such as a thermally or ultraviolet (UV) curable organic film, or chemically strengthened glass, such as soda-lime glass (SiO₂—CaO—Na₂O) or aluminosilicate glass (SiO₂—Al₂O₃—Na₂O). When the OLED device (FIG. 4) including the light extraction substrate 100 (FIG. 3) according to the one embodiment of the present disclosure is used for lighting, the base 110 may be formed from soda-lime glass. When the OLED device (FIG. 4) is used for a display system, the base 110 may be formed from aluminosilicate glass.

In the ion implantation step, ions are implanted into the base 110 through one surface of the base 110. Specifically, in the ion implantation step, the ions are implanted to a predetermined depth from the surface of the base 110. When the ions are implanted in this manner, the implanted ions are densely distributed at the predetermined depth within the base 110, thereby forming an ion implantation layer 120, i.e. a layer having a thickness of several hundred nanometers to several micrometers, within the base 110.

In this ion implantation step, ions to be implanted into the base 110 to form the ion implantation layer 120 may be formed using at least one selected from the candidate group consisting of H₂, Ar, He, and N₂. Here, the ion implantation may be performed using an ion implantation apparatus (not shown).

Subsequently, the heat treatment step is a step of applying heat energy to the ion implantation layer 120. The heat treatment step is also a step of forming a void layer comprised of a number of voids within the base 110, the refractive index of the voids being different from the refractive index of the base 110.

In the heat treatment step, thermal annealing is performed on the base 110 to apply heat energy to the ion implantation layer 120. When the base 110 having the ion implantation layer 120 therewithin is subjected to thermal annealing, heat energy is transferred to the ion implantation layer 120, thereby significantly increasing the mobility of ions of the ion implantation layer 120. At this time, the ions having the increased mobility gather with the adjacent ions, thereby being converted into gas. As illustrated in FIG. 3, the gas formed in this manner forms the number of voids 130 in the base 110, the refractive index of the voids 130 being different from the refractive index of the base 110. That is, the number of voids 130 formed in the base 110 by the heat treatment step are induced by the gasification of the ions of the ion implantation layer 120 formed within the base 110. Here, the number of voids 130 may be formed with random sizes and shapes.

As illustrated in FIG. 3, when the heat treatment step is completed, the light extraction substrate 100 for an OLED device including the base 110 and the number of voids 130 formed within the base 110, the refractive index of the voids 130 being different from the refractive index of the base 110, is manufactured.

Since the method of manufacturing the light extraction substrate for an OLED device according to the one embodiment of the present disclosure provides a simple process consisting of the ion implantation step and the heat treatment step as described above, the manufacturing process of the light extraction substrate 100 can be significantly simplified and the manufacturing costs and manufacturing time of the light extraction substrate 100 can be significantly reduced.

FIG. 4 is a cross-sectional view schematically illustrating the OLED device, with the light extraction substrate 100 manufactured according to the one embodiment of the present disclosure being disposed in a top portion thereof. Referring to FIG. 4, the OLED 10 has a multilayer structure comprised of an anode 11, an organic light-emitting layer 12, and a cathode 13. The anode 11 is a transparent electrode that may be formed from, for example, a metal, such as Au, In, Sn, or a metal oxide, such as indium tin oxide (ITO), having a greater work function to facilitate hole injection. The cathode 13 may be a metal thin film formed from Al, Al:Li or Mg:Ag that has a smaller work function to facilitate electron injection. In addition, the organic light-emitting layer 12 may include a hole injection layer, a hole transport layer, an emission layer, an electron transport layer, and an electron injection layer that are sequentially stacked on the anode 11. When the OLED device according to the one embodiment of the present disclosure is a white OLED device used for lighting, the light-emitting layer may have, for example, a multilayer structure comprised of a high-molecular light-emitting layer that emits blue light and a low-molecular light-emitting layer that emits orange-red light, or a variety of other structures that emit white light may be used. In addition, the OLED 10 may have a tandem structure. In this case, a plurality of organic light-emitting layers 12 may alternate with interconnecting layers.

Since the OLED 10 has the above-described structure, when a forward voltage is induced between the anode 11 and the cathode 13, electrons migrate from the cathode 13 to the emission layer through the electron injection layer and the electron transport layer, while holes migrate from the anode 11 to the emission layer through the hole injection layer and the hole transport layer. The electrons and the holes that have migrated into the emission layer recombine with each other, thereby generating excitons. These excitons transit from an excited state to a ground state, thereby emitting light. The brightness of the emitted light is proportional to the amount of current that flows between the anode 11 and the cathode 13.

When the light extraction substrate 100 manufactured according to the one embodiment of the present disclosure is provided or disposed on the anode 11, or the transparent electrode, of the above-described OLED, the difference in refractive indices between the base 110 and the number of voids 130 can improve the extraction efficiency of light generated by the organic light-emitting layer 12. The number of voids 130 can act to scatter light emitted from the organic light-emitting layer 12 through a variety of paths. This can consequently further improve the light extraction efficiency of the OLED device, so that the OLED device can be driven at a low current level. It is thereby possible to reduce the power consumption of a lighting system or a display device using the OLED 10 as a light source while improving the luminance thereof.

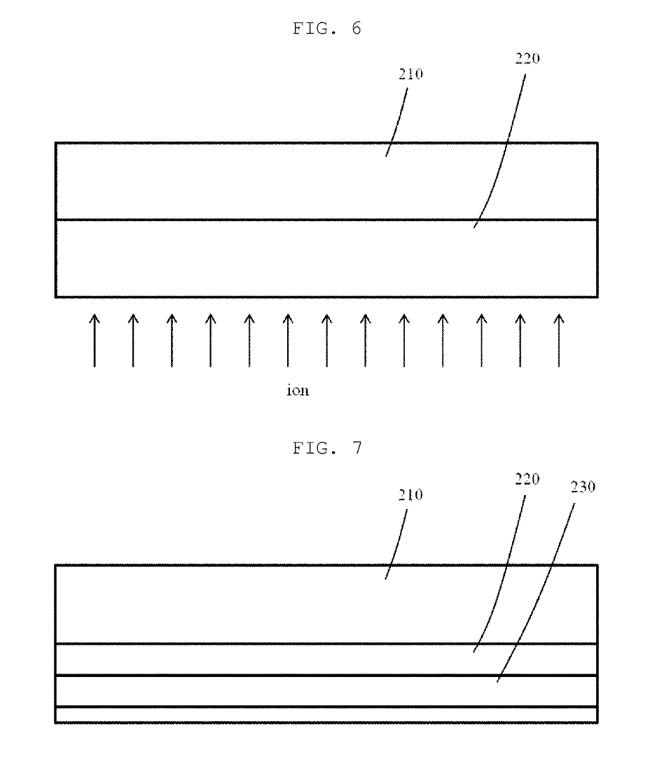

Hereinafter, a method of manufacturing a light extraction substrate for an OLED device according to another embodiment of the present disclosure will be described in detail with reference to FIG. 5 to FIG. 9.

The method of manufacturing the light extraction substrate according to the another embodiment of the present disclosure includes a metal oxide layer forming step, an ion implantation step, and a heat treatment step.

First, as illustrated in FIG. 5, the metal oxide layer forming step is a step of forming a metal oxide layer 220 on a base 210, the metal oxide layer 220 being formed from a metal oxide having a first refractive index. The base 210 acts to protect the metal oxide layer 220 and an OLED 10 from the external environment while serving as a pathway, along which light generated by the OLED exits. The base 210 may be formed from the same material as the base 110 (FIG. 1) according to the one embodiment of the present disclosure.

In the metal oxide layer forming step, the metal oxide layer 220 may be formed from one metal oxide selected from among ZnO, Al₂O₃, TiO₂, SnO₂, ZrO₂, and SiO₂.

As illustrated in FIG. 6 and FIG. 7, the subsequent ion implantation step is a step of forming an ion implantation layer 230 within the metal oxide layer 220 by implanting ions into the metal oxide layer 220 through one surface of the metal oxide layer 220. Since the ion implantation step according to the another embodiment of the present disclosure is substantially the same process as the ion implantation step according to the one embodiment of the present disclosure, except for an object into which ions are implanted, detailed descriptions thereof will be omitted. mom Next, the heat treatment step is a step of applying heat energy to the ion implantation layer 230. In addition, the heat treatment step is a step of forming a void layer comprised of a number of voids within the metal oxide layer 220 by such heat energy application, the refractive index of the voids being different from the refractive index of the metal oxide layer 220.

The heat treatment step according to the another embodiment of the present disclosure is substantially the same process as the heat treatment step according to the one embodiment of the present disclosure. Thus, the mobility of ions of the ion implantation layer 230 is significantly increased by heat energy, so that the ions form the number of voids 240 within the metal oxide layer 220 in the same mechanism as ions according to the one embodiment of the present disclosure. Here, the number of voids 130 formed may have random sizes and shapes.

As illustrated in FIG. 8, when the heat treatment step is completed, the light extraction substrate 200 for an OLED device including the base 210, the metal oxide layer 220 disposed on one surface of the base 210, and the number of voids 240 formed within the metal oxide layer 220, the refractive index of the voids 240 being different from the refractive index of the metal oxide layer 220, is manufactured.

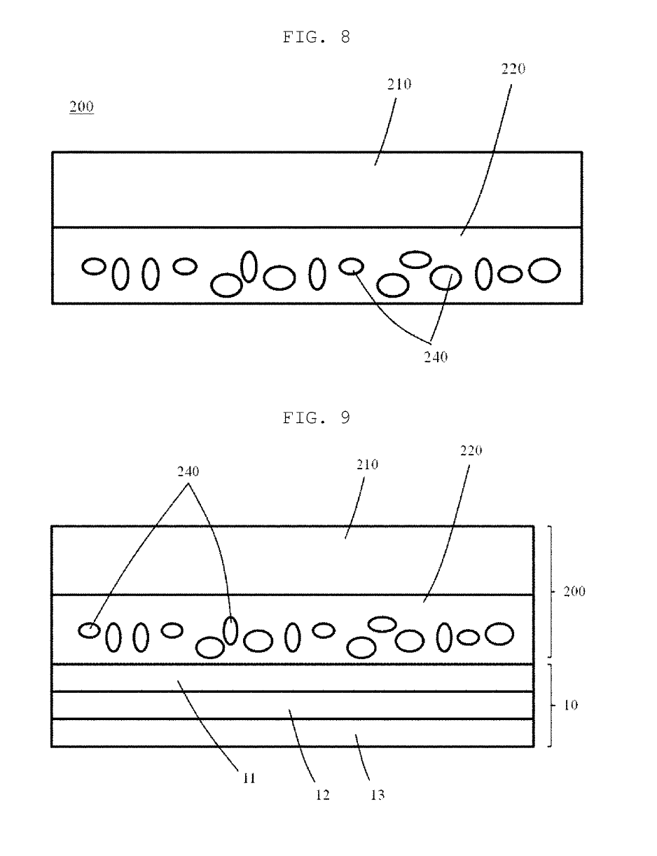

As illustrated in FIG. 9, the light extraction substrate 200 for an OLED device manufactured according to the another embodiment of the present disclosure may be disposed in a portion of the OLED device, through which light generated by an OLED 10 of the OLED device exits. Here, the metal oxide layer 220 of the light extraction substrate 200 serves as an internal light extraction layer of the OLED device. Since the number of voids 240 are formed within the metal oxide layer 220, the surface of the metal oxide layer 220 in contact with the anode 11, or the transparent electrode, of the OLED 10 is a high flat surface. Thus, a planarization layer conventionally provided between the light extraction layer and the anode 11 can be omitted.

As set forth above, the method of manufacturing a light extraction substrate for an OLED device manufactured according to the another embodiment of the present disclosure not only can improve the light extraction efficiency of the OLED device, but can also simplify the manufacturing process of the light extraction substrate 200 and significantly reduce the manufacturing costs and manufacturing time of the light extraction substrate 200, using the simple processes of ion implantation and heat treatment, like the one embodiment of the present disclosure.

The foregoing descriptions of specific exemplary embodiments of the present disclosure have been presented with respect to the drawings. They are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

1. A method of manufacturing a light extraction substrate for an organic light-emitting diode device, the method comprising:
forming an ion implantation layer within a base to be disposed on a transparent electrode of an organic light-emitting diode by implanting ions into the base through a surface of the base; and
forming a void layer comprising a number of voids within the base by applying heat energy to the ion implantation layer, a refractive index of the number of voids being different from a refractive index of the base, wherein the number of voids are induced by gasification of the ions.

2. The method of claim 1, wherein the base comprises a transparent substrate formed from a thermally or ultraviolet curable polymeric material, soda-lime glass, or aluminosilicate glass.

3. The method of claim 1, wherein the ions used in forming the ion implantation layer are formed from at least one selected from a candidate group consisting of H₂, Ar, He, and N₂.

4. A method of manufacturing a light extraction substrate for an organic light-emitting diode device, the method comprising:
forming a metal oxide layer on a base, the metal oxide layer being formed from a metal oxide having a first refractive index;
forming an ion implantation layer within the metal oxide layer by implanting ions into the metal oxide layer through a surface of the metal oxide layer; and
forming a void layer comprising a number of voids within the metal oxide layer by applying heat energy to the ion implantation layer, the number of voids having a second refractive index, wherein the number of voids are induced by gasification of the ions.

5. The method of claim 4, wherein the metal oxide used in forming the metal oxide layer comprises one selected from the group consisting of ZnO, Al₂O₃, TiO₂, SnO₂, ZrO₂, and SiO₂.

6. The method of claim 4, wherein the ions used in forming the ion implantation layer are formed from at least one selected from a candidate group consisting of H₂, Ar, He, and N₂.

7. The method of claim 4, wherein an exposed surface of the metal oxide layer is to be in contact with a transparent electrode of an organic light-emitting diode.

8-11. (canceled)
